(19) United States
(12) Patent Application Publication
(10) Pub. No.: US 2017/0075758 A1
(43) Pub. Date: Mar. 16, 2017

(54) MEMORY SYSTEM AND METHOD OF CONTROLLING NONVOLATILE MEMORY

(71) Applicant: Kabushiki Kaisha Toshiba, Minato-ku (JP)

(72) Inventors: Riki SUZUKI, Yokohama (JP); Toshikatsu HIDA, Yokohama (JP)

(73) Assignee: Kabushiki Kaisha Toshiba, Minato-ku (JP)

(21) Appl. No.: 15/066,439

(22) Filed: Mar. 10, 2016

Related U.S. Application Data
(60) Provisional application No. 62/216,654, filed on Sep. 10, 2015.

(51) Int. Cl. G06F 11/10; G06F 3/06; G11C 29/52

(52) U.S. Cl. CPC G06F 11/1068; G11C 29/52; G06F 3/0619; G06F 3/064; G06F 3/0679

(57) ABSTRACT

According to one embodiment, when a write request of first data is received, a controller selects one frame type from among a plurality of frame types including first and second frame types based on information including defective memory cell information of nonvolatile memory and generates a codeword including the first data and in correspondence with the selected frame type. In a case where the first frame type is selected, the controller generates a frame corresponding to the first frame type based on the information and the codeword and writes the generated frame corresponding to the first frame type into the nonvolatile memory.

### CROSS-REFERENCE TO RELATED APPLICATIONS

This application is based upon and claims the benefit of priority from U.S. Provisional Application No. 62/216,654, filed on Sep. 10, 2015; the entire contents of which are incorporated herein by reference.

### FIELD

Embodiments described herein relate generally to a memory system including nonvolatile memory and a method of controlling nonvolatile memory.

### BACKGROUND

As a method of recovering data stored in a defective memory cell arranged inside nonvolatile memory, generally, an error correction process is executed.

### BRIEF DESCRIPTION OF THE DRAWINGS

FIG. 1 is a block diagram that illustrates an example of the configuration of a memory system according to an embodiment;

FIG. 2 is a diagram that illustrates an example of the configuration of a semiconductor memory unit according to an embodiment;

FIG. 3 is a diagram that illustrates an example of the configuration of a block of a memory cell array having a two-dimensional structure;

FIG. 4 is a diagram that illustrates an example of the configuration of a block of a memory cell array having a three-dimensional structure;

FIG. 5 is a cross-sectional view of a partial area of a memory cell array of NAND memory having a three-dimensional structure;

FIG. 6 is a diagram that illustrates an example of the configuration of an encoder/decoder and a storage location control unit according to an embodiment;

FIG. 7 is a diagram that illustrates a correspondence between data corresponding to one page and a physical address according to this embodiment;

FIG. 8 is a diagram that illustrates first to fourth frame types according to an embodiment;

FIG. 9 is a diagram that illustrates defective cell number information;

FIG. 10 is a diagram that illustrates a skipping process according to this embodiment;

FIG. 11 is a diagram that illustrates a substitution process according to this embodiment;

FIG. 12 is a flowchart that illustrates an example of a write processing sequence according to this embodiment; and

FIG. 13 is a flowchart that illustrates an example of a reading processing sequence according to an embodiment.

### DETAILED DESCRIPTION

According to one embodiment, a memory system includes nonvolatile memory and a controller. The controller manages information including defective memory cell information of the nonvolatile memory. When a write request including first data is received, the controller selects one frame type from among a plurality of frame types including first and second frame types based on the information and generates a codeword including the first data and in correspondence with the selected frame type. The first frame type includes a first codeword and a first alternative area. The first codeword includes data having a first length and redundant data having a second length. The first alternative area has a third length. The second frame type includes a second codeword and a second alternative area. The second codeword includes data having the first length and redundant data having a fourth length. The second alternative area has a fifth length. The second length is longer than the fourth length. The third length is shorter than the fifth length. The plurality of frame types have a same sixth length. In a case where selecting the first frame type, the controller generates a frame corresponding to the first frame type having the sixth length based on the information and the first codeword and writes the generated frame corresponding to the first frame type into the nonvolatile memory. In a case where selecting the second frame type, the controller generates a frame corresponding to the second frame type having the sixth length based on the information and the second codeword and writes the generated frame corresponding to the second frame type into the nonvolatile memory.

Exemplary embodiments of memory system and a method of controlling nonvolatile memory will be described below in detail with reference to the accompanying drawings. The present invention is not limited to the following embodiments.

### First Embodiment

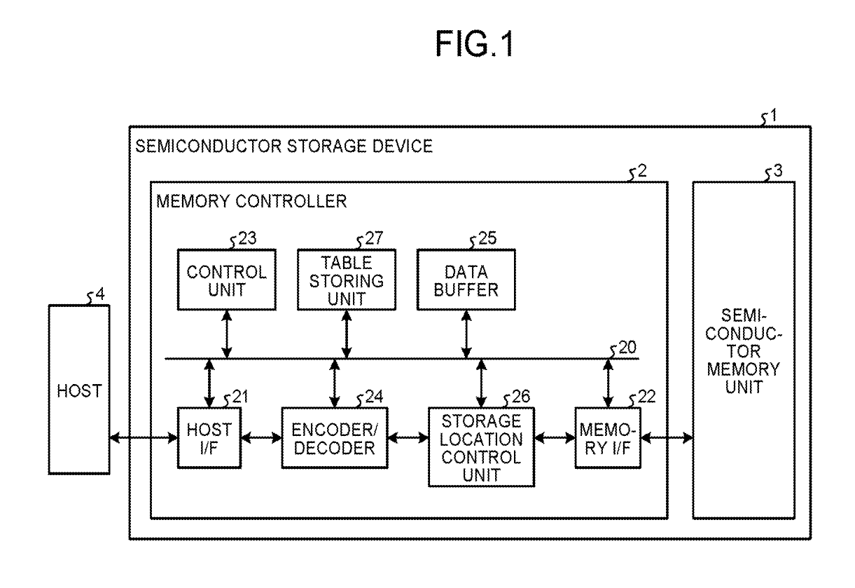

FIG. 1 is a block diagram that illustrates an example of the configuration of a memory system 1 according to a first embodiment. The memory system 1 is connectable to a host apparatus (hereinafter, abbreviated as a host) 4 and functions as an external storage device of the host 4. The host 4, for example, may be an information processing apparatus such as a personal computer, a mobile phone, or an imaging apparatus, may be a mobile terminal such as a tablet computer or a smart phone, a gaming device, or an in-vehicle terminal such as a car navigation system.

The memory system 1 includes a memory controller 2 and a semiconductor memory unit (nonvolatile memory) 3. The semiconductor memory unit 3 is nonvolatile memory storing data in a nonvolatile manner and, for example, is NAND flash memory (hereinafter, abbreviated as NAND memory). Here, while an example in which the NAND memory is used as the semiconductor memory unit 3 will be described, as the semiconductor memory unit 3, a storage unit other than the NAND memory such as flash memory having a three-dimensional structure, resistance random access memory (ReRAM), or ferroelectric random access memory (FeRAM) may be used. In addition, here, while an example in which a semiconductor memory is used as the storage unit will be described, an error correction process according to this embodiment may be applied to a storage device using a storage unit other than the semiconductor memory.

The memory controller 2 controls writing data into the semiconductor memory unit 3 in accordance with a write command (request) transmitted from the host 4. In addition, the memory controller 2 controls reading data from the semiconductor memory unit 3 in accordance with a read command transmitted from the host 4. The memory controller 2 includes: a host interface (host I/F) 21; a memory interface (memory I/F) 22; a control unit 23; an encoder/decoder 24; a data buffer 25; and a storage location control unit 26. The host I/F 21, the memory I/F 22, the control unit 23, the encoder/decoder 24, the data buffer 25, the storage location control unit 26, and a table storing unit 27 are interconnected through an internal bus 20.

The host I/F 21 executes a process according to an interface standard with the host 4 and outputs a command, user data, and the like received from the host 4 to the internal bus 20. In addition, the host I/F 21 transmits user data read from the semiconductor memory unit 3, a response from the control unit 23, and the like to the host 4. In this embodiment, data written into the semiconductor memory unit 3 according to a write request from the host 4 will be referred to as user data.

The memory I/F 22 executes a writing process of write data into the semiconductor memory unit 3 based on an instruction from the control unit 23. In addition, based on an instruction from the control unit 23, the memory I/F 22 executes a reading process of data from the semiconductor memory unit 3.

The control unit 23 is a control unit that controls the overall operation of each constituent element of the semiconductor storage device 1 and, for example, is configured by a central processing unit (CPU), a micro controller unit (MPU), and the like. In a case where a command is received from the host 4 through the host I/F 21, the control unit 23 executes a control process according to the command. For example, the control unit 23 instructs the memory I/F 22 to write user data and parity into the semiconductor memory unit 3 in accordance with a command from the host 4. In addition, the control unit 23 instructs the memory I/F 22 to read user data and parity from the semiconductor memory unit 3 in accordance with a command from the host 4. Furthermore, data other than the user data, in other words, data (hereinafter, referred to as management data) used for the internal control of the semiconductor storage device 1 may be stored in the semiconductor memory unit 3. In such a case, the control unit 23 also instructs the memory I/F 22 to write and read such management data.

The control unit 23 determines a storage area (storage location) on the semiconductor memory unit 3 for user data accumulated in the data buffer 25. The user data is stored in the data buffer 25 through the internal bus 20. The control unit 23 determines a memory area for each data (page data) in units of pages that are writing units. In description presented here, memory cells that are commonly connected to one word line are defined as a memory cell group. In a case where the memory cells are multi-level cells, the memory cell group corresponds to a plurality of pages. For example, in a case where multi-level cells each capable of storing two bits (two bits/cell) are used, the memory cell group corresponds to two pages. On the other hand, in a case where multi-level cells each capable of storing three bits (three bits/cell) are used, the memory cell group corresponds to three pages. In description presented here, user data written into one page is defined as unit data. The data of the semiconductor memory unit 3 is erased in units called blocks. One block includes a plurality of memory cell groups.

The control unit 23 determines a memory area of the semiconductor memory unit 3 at a writing destination for each unit data. Physical addresses are assigned to the memory area of the semiconductor memory unit 3. The control unit 23 manages the memory area at the writing destination of the unit data by using the physical addresses. The control unit 23 designates the determined memory area (the physical address) and instructs the memory I/F 22 to write user data into the semiconductor memory unit 3. A correspondence between the logical address of user data received from the host 4 and a physical address representing a storage area on the semiconductor memory unit 3 in which the user data is stored is stored in the table storing unit 27 as an address translation table. The logical address is an address of the user data managed by the host 4. The address translation table may be either a table that directly represents the correspondence between a logical address and a physical address or multi-step tables. The multi-step tables are a plurality of tables used for transforming a logical address into an intermediate address once and transforming the intermediate address into a physical address.

In addition, in a case where a read request is received from the host 4, the control unit 23 translates a logical address specified by the read request into a physical address by using the address translation table described above and instructs the memory I/F 22 to read data from the physical address. As will be described later, in this embodiment, since the data obtained by dividing the unit data into plural pieces of data is encoded to generate codewords, a plurality of codewords are included in the data of a unit of writing (that is, the data of one page). In this embodiment, the physical address in the address conversion table is managed in a codeword unit in order to enable the reading from the semiconductor memory unit 3 in the codeword unit. Further, when the reading from the semiconductor memory unit 3 in the codeword unit is performed, the data of one page containing the codeword instructed for the reading is once read out of the semiconductor memory unit 3. Then, the semiconductor memory unit 3 outputs the codeword instructed for the reading in the data of one page to the memory controller 2.

The data buffer 25 temporarily stores user data received by the memory controller 2 from the host 4 before storing the user data in the semiconductor memory unit 3. In addition, the data buffer 25 temporarily stores user data read from the semiconductor memory unit 3 before transmitting the user data to the host 4. For example, the data buffer 25 is configured by a general-purpose memory such as static random access memory (SRAM) or dynamic random access memory (DRAM).

The user data transmitted from the host 4 is transmitted to the internal bus 20 and is stored in the data buffer 25. The encoder/decoder 24 generates a codeword by coding data (the user data and the management data) stored in the semiconductor memory unit 3. A coding system for the user data and a coding system for the management data may be different from each other. In addition, as the coding system, any system may be used. For example, Reed Solomon (RS) coding, Bose Chaudhuri Hocquenghem (BCH) coding, low density parity check (LDPC) coding, or the like may be used. The encoder/decoder 24 executes a decoding process of the codewords read from the semiconductor memory unit 3.

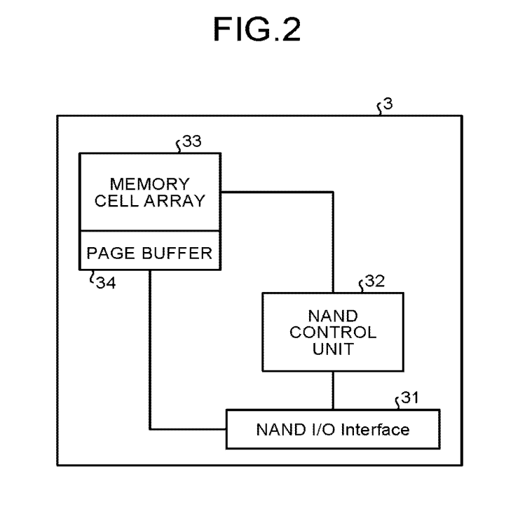

As described above, in this embodiment, the semiconductor memory unit 3 is the NAND memory. FIG. 2 is a diagram that illustrates an example of the configuration of the semiconductor memory unit 3 according to this embodiment. As illustrated in FIG. 2, the semiconductor memory unit 3 includes: a NAND I/O interface 31; a NAND control unit 32; a memory cell array (NAND memory cell array) 33; and a page buffer 34.

In a case where a command such as a write request or a read request is input from the outside, the NAND I/O interface 31 inputs the command to the NAND control unit 32 by controlling the input/output from/to an external device such as the memory controller 2. The NAND control unit 32 controls the operation of the semiconductor memory unit 3 based on a command or the like input from the NAND I/O interface 31. More specifically, in a case where a write request is input, data requested to be written is controlled so as to be written into a designated area on the memory cell array 33. In addition, in a case where a read request is input, the NAND control unit 32 executes control such that data requested to be read is read from the memory cell array 33. The data read from the memory cell array 33 is stored in the page buffer 34. In this embodiment, at the time of reading data, as described above, the data can be read in units of codewords each being smaller than the page unit. In a case where data is requested to be read in units of codewords, data requested to be read from among data stored in the page buffer 34 is output to the memory controller 2.

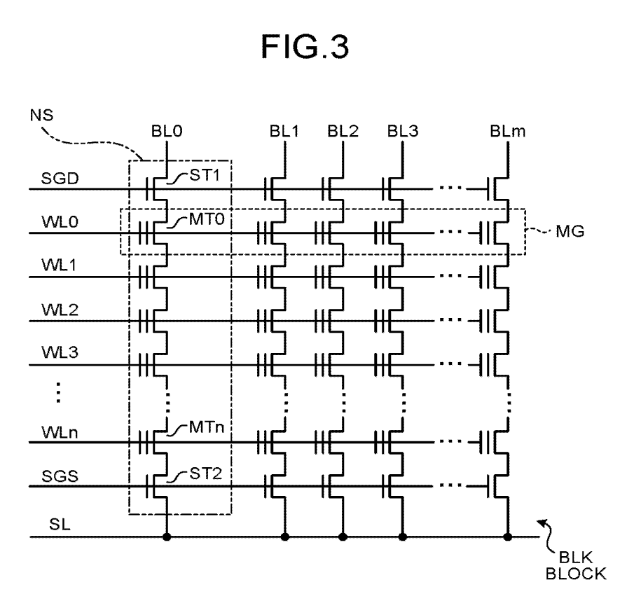

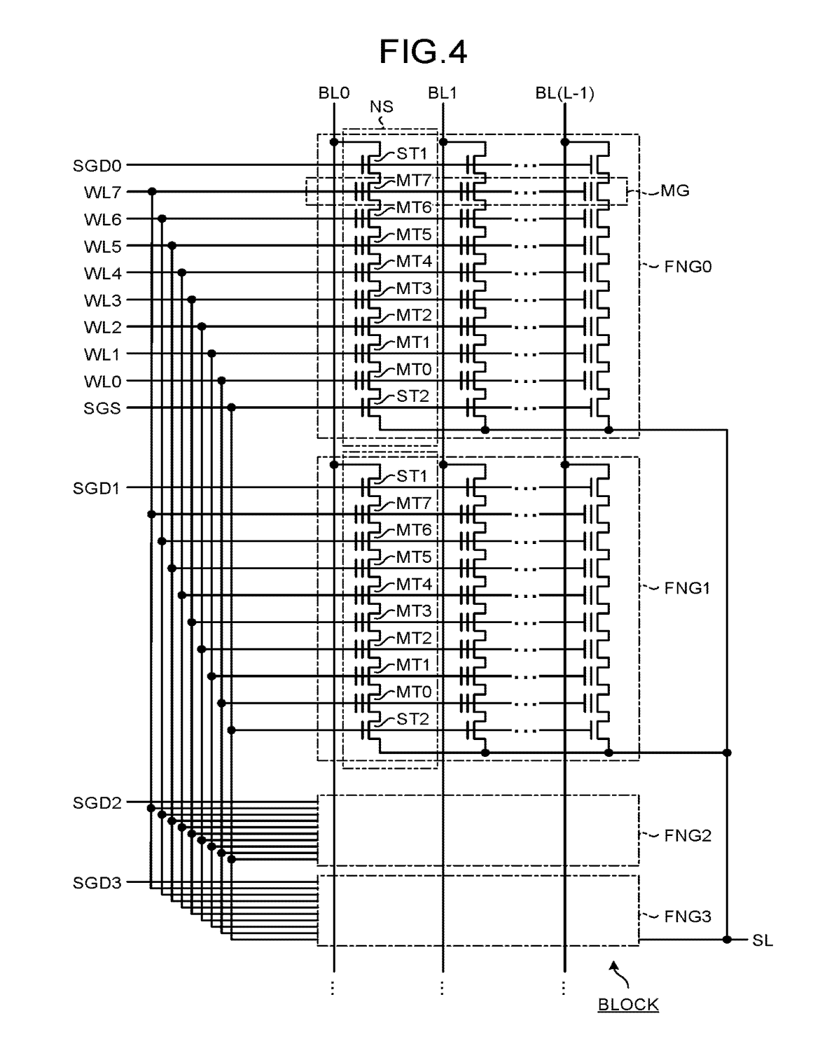

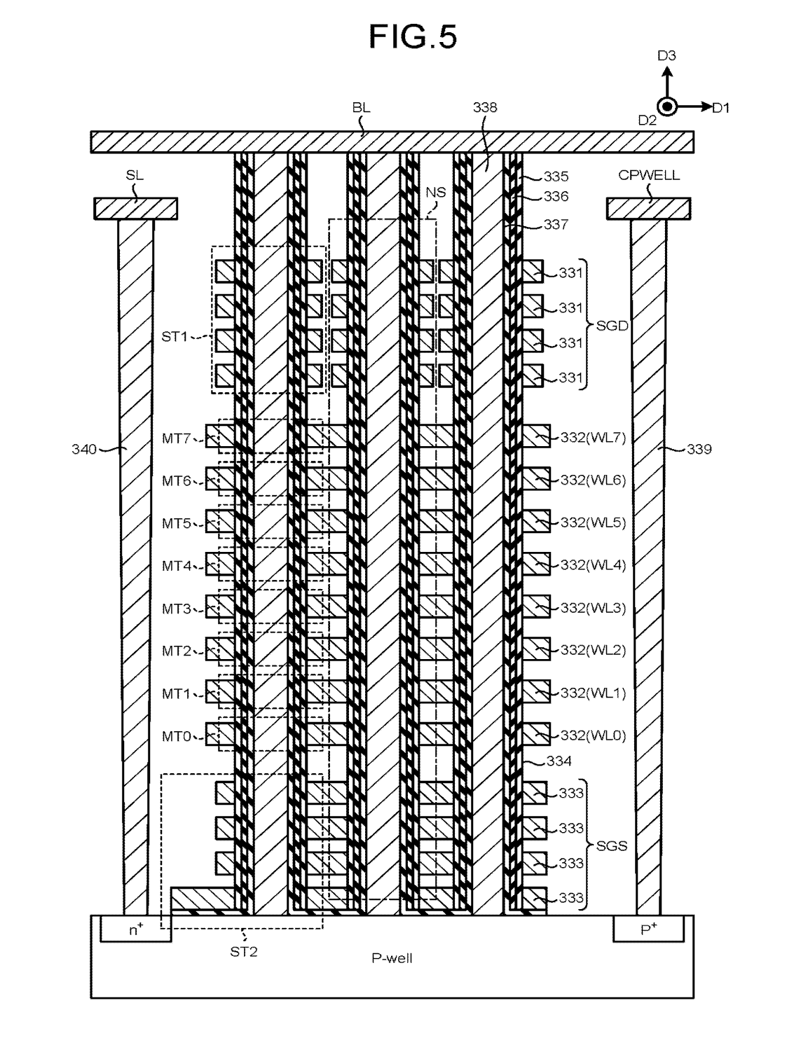

The memory cell array 33 that is a premise of this embodiment is not particularly limited to a specific configuration but may be a memory cell array having a two-dimensional structure as illustrated in FIG. 3, a memory cell array having a three-dimensional structure as illustrated in FIGS. 4 and 5, or a memory cell array having any other structure.

FIG. 3 is a diagram that illustrates an example of the configuration of a block of a memory cell array having a two-dimensional structure. FIG. 3 illustrates one of a plurality of blocks that configure the memory cell array having the two-dimensional structure. The other blocks of the memory cell array have the same configuration as that illustrated in FIG. 3. As illustrated in FIG. 3, the block BLK of the memory cell array includes (m+1) (here, m is an integer of “0” or more) NAND strings NS. Each NAND string NS shares a diffusion region (a source region or a drain region) between memory cell transistors MT adjacent to each other. Each NAND string NS includes: (n+1) (here, n is an integer of “0” or more) memory cell transistors MT0 to MTn connected in series; and selection transistors ST1 and ST2 arranged at both ends of the column of the (n+1) memory cell transistors MT0 to MTn.

Word lines WL0 to WLn are respectively connected to control gate electrodes of the memory cell transistors MT0 to MTn that configure the NAND string NS, and, memory cell transistors MTi (here, i=0 to n) included in each NAND string NS are connected to be common using the same word line WLi (here, i=0 to n). In other words, the control gate electrodes of the memory cell transistors MTi disposed in the same row within the block BLK are connected to the same word line WLi.

Each of the memory cell transistors MT0 to MTn is configured by a field effect transistor having a stacked gate structure on a semiconductor substrate. Here, the stacked gate structure includes: a charge storage layer (floating gate electrode) formed on the semiconductor substrate with a gate insulating film being interposed therebetween; and a control gate electrode formed on the charge storage layer with an inter-gate insulating film being interposed therebetween. A threshold voltage of each of the memory cell transistors MT0 to MTn changes according to the number of electrons storable in the floating gate electrode and thus, can store data according to a difference in the threshold voltage.

Bit lines BL0 to BLm are respectively connected to the drains of (m+1) selection transistors ST1 within one block BLK, and a selection gate line SGD is connected to be common to the gates of the selection transistors. In addition, the source of the selection transistor ST1 is connected to the drain of the memory cell transistor MT0. Similarly, a source line SL is connected to be common to the sources of the (m+1) selection transistors ST2 within one block BLK, and a selection gate line SGS is connected to be common to the gates of the selection transistors ST2. In addition, the drain of the selection transistor ST2 is connected to the source of the memory cell transistor MTn.

Each memory cell is connected not only to the word line but also to the bit line. Each memory cell can be identified by using an address used for identifying a word line and an address used for identifying a bit line. As described above, the data of the plurality of memory cells (the memory cell transistors MT) disposed within the same block BLK is erased altogether. On the other hand, data is written and read in units of memory cell groups MG. One memory cell group MG includes a plurality of memory cells connected to one word line.

In a read operation and a programming operation, one word line is selected according to the physical address, and one memory cell group MG is selected. A switching of the page within the memory cell group MG is executed using the physical address.

FIG. 4 is a diagram that illustrates an example of the configuration of a block of a memory cell array having a three-dimensional structure. FIG. 4 illustrates one block BLK among a plurality of blocks configuring the memory cell array having the three-dimensional structure. Another block of the memory cell array has a configuration similar to that illustrated in FIG. 4.

As illustrated in the drawing, the block BLK, for example, includes four fingers FNG (FNG0 to FNG3). In addition, each finger FNG includes a plurality of NAND strings NS. Each NAND string NS, for example, includes eight memory cell transistors MT (MT0 to MT7) and selection transistors ST1 and ST2. Here, the number of memory cell transistors MT is not limited to eight. The memory cell transistor MT is arranged between the selection transistors ST1 and ST2 such that the current paths thereof are connected in series. The current path of the memory cell transistor MT7 disposed on one end side of the series connection is connected to one end of the current path of the selection transistor ST1, and the current path of the memory cell transistor MT0 disposed on the other end side is connected to one end of the current path of the selection transistor ST2.

The gates of the selection transistors ST1 of the fingers FNG0 to FNG3 are commonly connected respectively to selection gate lines SGD0 to SGD3. On the other hand, the gates of the selection transistors ST2 are commonly connected to the same selection gate line SGS among a plurality of fingers FNG. In addition, the control gates of the memory cell transistors MT0 to MT7 disposed inside a same block BLK0 are commonly connected to word lines WL0 to WL7. In other words, while the word lines WL0 to WL7 and the selection gate lines SGS are commonly connected among the plurality of fingers FNG0 to FNG3 disposed inside a same block BLK, the selection gate line SGD is independent for each of the fingers FNG0 to FNG3 even inside the same block BLK.

The word lines WL0 to WL7 are connected to the control gate electrodes of the memory cell transistors MT0 to MT7 configuring the NAND string NS, and the memory cell transistors MTi (i=0 to n) of each NAND string NS are commonly connected by a same word line WLi (i=0 to n). In other words, the control gate electrodes of the memory cell transistors MTi disposed in the same row disposed inside the block BLK are connected to a same word line WLi.

Each memory cell is connected to a word line and a bit line. Each memory cell can be identified by using an address used for identifying a word line and selection gate lines SGD0 to SGD3 and an address used for identifying a bit line. As described above, data of memory cells (memory cell transistors MT) disposed inside a same block BLK is erased together. On the other hand, data reading and data writing are executed in units of memory cell groups MG. One memory cell group MG includes a plurality of memory cells that are connected to one word line WL and belong to one finger FNG.

When a read operation or a programming operation is executed, one word line WL and one selection gate line SGD are selected according to a physical address, whereby a memory cell group MG is selected.

FIG. 5 is a cross-sectional view of a partial area of a memory cell array of NAND memory having a three-dimensional structure. As illustrated in FIG. 5, a plurality of NAND strings NS are formed on a P-well region. In other words, on the P-well region, a plurality of wiring layers 333 serving as selection gate lines SGS, a plurality of wiring layers 332 serving as word lines WL, and a plurality of wiring layers 331 serving as selection gate lines SGD are formed.

A memory hole 334 that arrives at the P-well region through such wiring layers 333, 332, and 331 is formed. On the side face of the memory hole 334, a block insulating film 335, a charge storage layer 336, and a gate insulating film 337 are sequentially formed, and a conductive film 338 is embedded inside the memory hole 334. The conductive film 338 functions as a current path of the NAND string NS and is an area in which a channel is formed when the memory cell transistors MT and the selection transistors ST1 and ST2 operate.

In each NAND string NS, on the P-well region, the selection transistor ST2, a plurality of the memory cell transistors MT, and the selection transistor ST1 are sequentially stacked. At the upper end of the conductive film 338, a wiring layer serving as a bit line BL is formed.

In addition, inside the front face of the P-well region, an n+ type impurity diffusion layer and a p+ type impurity diffusion layer are formed. On the n+ type impurity diffusion layer, a contact plug 340 is formed, and a wiring layer serving as a source line SL is formed on the contact plug 340. In addition, on the p+ type impurity diffusion layer, a contact plug 339 is formed, and a wiring layer serving as a well wiring CPWELL is formed on the contact plug 339.

A plurality of the configurations illustrated in FIG. 5 are arranged in a depth direction of the sheet of FIG. 5, and one finger FNG is formed by a set of a plurality of NAND strings aligned in one line in the depth direction.

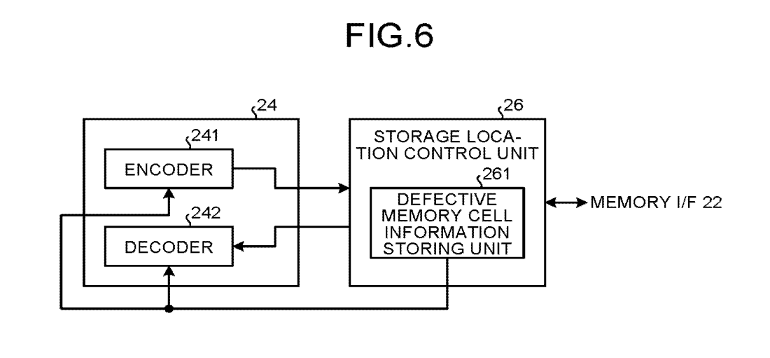

Next, a writing process and a reading process according to this embodiment will be described. FIG. 6 is a diagram that illustrates an example of the configuration of the encoder/decoder 24 and the storage location control unit 26 according to this embodiment. The encoder/decoder 24 includes an encoder 241 and a decoder 242. The storage location control unit 26 includes a defective memory cell information storing unit 261. In FIG. 6, while an example in which the storage location control unit 26 is independently arranged is illustrated, the storage location control unit 26 may be arranged inside the memory I/F 22 or may be arranged inside the control unit 23.

The encoder 241 encodes division data which is data obtained by dividing the unit data into plural pieces of data to generate a codeword. The codeword generated by the encoder 241 is input to the storage location control unit 26. The storage location control unit 26 stores defective memory cell information (defective information) in the defective memory cell information storing unit 261. The defective memory cell information represents a location of a defective memory cell (defective memory area) of the semiconductor memory unit 3. The defective memory cell information, for example, may be information of a bit map pattern representing a defective memory cell or not for each semiconductor memory cell or information specifying the location of a defective memory cell and may have any arbitrary format.

The defective memory cell information is assumed to be acquired at the time of a test before the shipment of the semiconductor memory unit 3 and be stored in the defective memory cell information storing unit 261. For example, at the time of a test before the shipment, by inputting a command used for acquiring the defective memory cell information to the semiconductor memory unit 3, the defective memory cell information is acquired from the semiconductor memory unit 3. In addition, also after the shipment, this command may be configured to be inputtable from the memory controller 2 to the semiconductor memory unit 3 for updating the defective memory cell information.

The storage location control unit 26 executes a process for writing a codeword output from the encoder 241 into the semiconductor memory unit 3 with a defective memory cell being avoided based on the defective memory cell information. In a case where a defective memory cell disposed inside the nonvolatile memory can be specified, the processing cost is lower in a case where a codeword is written into a normal memory cell of the semiconductor memory unit 3 with a defective memory cell being avoided than in a case where data stored in a defective memory cell is recovered by an error correction process. More specifically, for example, as will be described later, a skipping process for writing a codeword output from the encoder 241 with a defective memory cell being skipped, a substitution process for writing data into an alternative area determined in advance instead of writing the data in a defective memory cell, and the like are executed, and redundant frame data (defect avoidance data) that is a result of such processes is output to the memory I/F 22. Hereinafter, a process for writing data into the semiconductor memory unit 3 with a defective memory cell being avoided will be referred to also as a defective cell avoiding process. The memory I/F 22 outputs the redundant frame data output from the storage location control unit 26 to the semiconductor memory unit 3 together with a physical address (a storage location on the semiconductor memory unit 3) specified by the control unit 23. In addition, as described above, for allowing the encoder 241 to encode data acquired by dividing the unit data into a plurality of pieces, a plurality of pieces of redundant frame data is included in a writing unit (that is data corresponding to one page). The semiconductor memory unit 3 writes the redundant frame data output from the storage location control unit 26 to a storage location corresponding to the specified physical address.

At the time of reading data from the semiconductor memory unit 3, the memory I/F 22 instructs the semiconductor memory unit 3 to read the data by designating a physical address specified for reading from the control unit 23. The data (redundant frame data) read from the semiconductor memory unit 3 is input to the storage location control unit 26 through the memory I/F 22. The storage location control unit 26 determines whether or not a defective cell avoiding process has been executed for read data (redundant frame data) at the time of writing the data based on the defective memory cell information. In a case where the defective cell avoiding process has been executed, data corresponding to a codeword is restored by executing a process that is a reversal process of the defective cell avoiding process for the redundant frame data, and the restored data is input to the decoder 242. The data corresponding to this codeword is data having a possibility that an error is mixed in the written codeword. The decoder 242 decodes input data and, in a case where there is no error, writes data corresponding to the user data among the input data into the data buffer 25. On the other hand, in a case where there is an error in the input data, the decoder 242 corrects the error and writes data corresponding to the user data after the error correction into the data buffer 25.

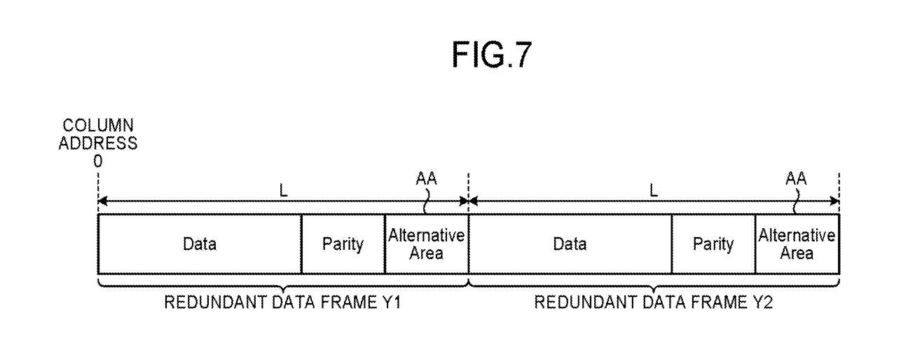

FIG. 7 is a diagram that illustrates a correspondence between data corresponding to one page and a physical address according to this embodiment. In this embodiment, the data corresponding to one page is divided into two redundant data frames including a redundant data frame Y1 and a redundant data frame Y2. The redundant data frames Y1 and Y2 have a same frame length L. Each of the redundant data frames Y1 and Y2 is configured by a codeword configured by data and parity and an alternative area AA. In FIG. 7, data represents divided unit data. In addition, parity represents a redundant bit (parity bits) generated in a coding process. The alternative area AA represents an area that is used for recovering a defective memory cell. In the case illustrated in FIG. 7, while one page is divided into two redundant data frames, one page may be divided into frames of an arbitrary number that is one or more.

A column address illustrated in FIG. 7 is an address that represents a bit line to which the memory cell of the semiconductor memory unit 3 is connected. In this embodiment, a location inside a page is managed by using a page address that is an address inside the semiconductor memory unit 3 in units of pages and a column address.

In this way, in this embodiment, instead of arranging the alternative area at the end of a memory area corresponding to one page altogether, the alternative area AA is assigned to each redundant data frame (each codeword) having the fixed length L. Accordingly, in this embodiment, when data is read in units of redundant data frames from the semiconductor memory unit 3, it is unnecessary to calculate the head address for reading, and a time deviation until the output of the read data disappears.

Here, in a case where a fixed size is assigned for an alternative area AA used for substituting a defective memory cell, when the number of defective memory cells is more than an assumed number, there is a possibility that a defective memory cell group or a defective block occurs without recovering all the defective memory cells. Thus, in this embodiment, the length of the parity and the length of the alternative area AA inside a redundant data frame are changed in accordance with the number of defective memory cells. In other words, in a case where the number of defective memory cells is large, the length of the parity is shortened, and the length of the alternative area AA is lengthened. On the other hand, in a case where the number of defective memory cells is small, the length of the parity is lengthened, and the length of the alternative area AA is shortened.

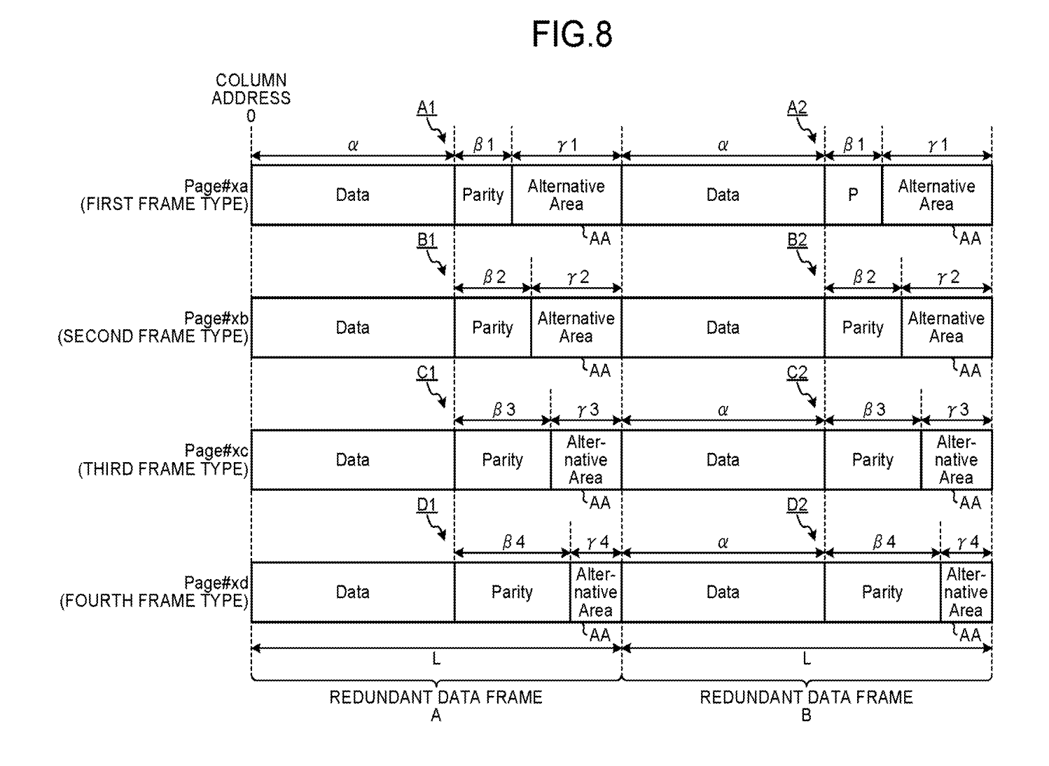

FIG. 8 is a diagram that illustrates correspondences between data and physical addresses in a plurality of mutually different pages. FIG. 8 illustrates redundant data frames A1 and A2 stored in page #xa, redundant data frames B1 and B2 stored in page #xb, redundant data frames C1 and C2 stored in page #xc, and redundant data frames D1 and D2 stored in page #xd.

In FIG. 8, page #xa belongs to a first group in which the number of defective memory cells inside the page is the largest. In addition, page #xb belongs to a second group in which the number of defective memory cells inside the page is second largest, page #xc belongs to a third group in which the number of defective memory cells inside the page is second smallest, and page #xd belongs to a fourth group in which the number of defective memory cells inside the page is the smallest. Here, E1>E2>E3. In other words, the number of defective memory cells inside page #xa is more than the threshold E1. The number of defective memory cells inside page #xb is more than the threshold E2 and the threshold E1 or less. The number of defective memory cells inside page #xc is more than the threshold E3 and the threshold E2 or less. The number of defective memory cells inside page #xd is the threshold E3 or less.

The redundant data frames A1 and A2 stored in page #xa belonging to the first group have a first frame structure (first frame type). In the first frame structure, data having a length of α, parity having a length of β1, and an alternative area AA having a length of γ1 are included. The redundant data frames B1 and B2 stored in page #xb belonging to the second group have a second frame structure (second frame type). In the second frame structure, data having a length of α, parity having a length of β2, and an alternative area AA having a length of γ2 are included. The redundant data frames C1 and C2 stored in page #xc belonging to the third group have a third frame structure (third frame type). In the third frame structure, data having a length of α, parity having a length of β3, and an alternative area AA having a length of γ3 are included. The redundant data frames D1 and D2 stored in page #xd belonging to the fourth group have a fourth frame structure (fourth frame type). In the fourth frame structure, data having a length of α, parity having a length of β4, and an alternative area AA having a length of γ4 are included. Here, β1<β2<β3<β4. In addition, γ1>γ2>γ3>γ4. As the number of types of frame structures (frame types), any arbitrary number of two or more may be employed.

As described above, in this embodiment, data corresponding to one page is associated with a column address. The data stored in page #xa will now be described. The redundant data frame A1 having a bit length L (=α+β1+γ1) that is output from the storage location control unit 26 is stored in an area of column address 0 to column address (α+β1+γ1−1), and the redundant data frame A2 having a bit length L (=α+β1+γ1) is stored in an area of column address (α+β1+γ1) to column address 2 (α+β1+γ1)−1. In addition, while not illustrated in FIG. 8, the column address 2 (α+β1+γ1)−1 of each page may be a last column address of each page, and, a surplus area may be arranged in an area of column address 2 (α+β1+γ1) to the last column address of each page.

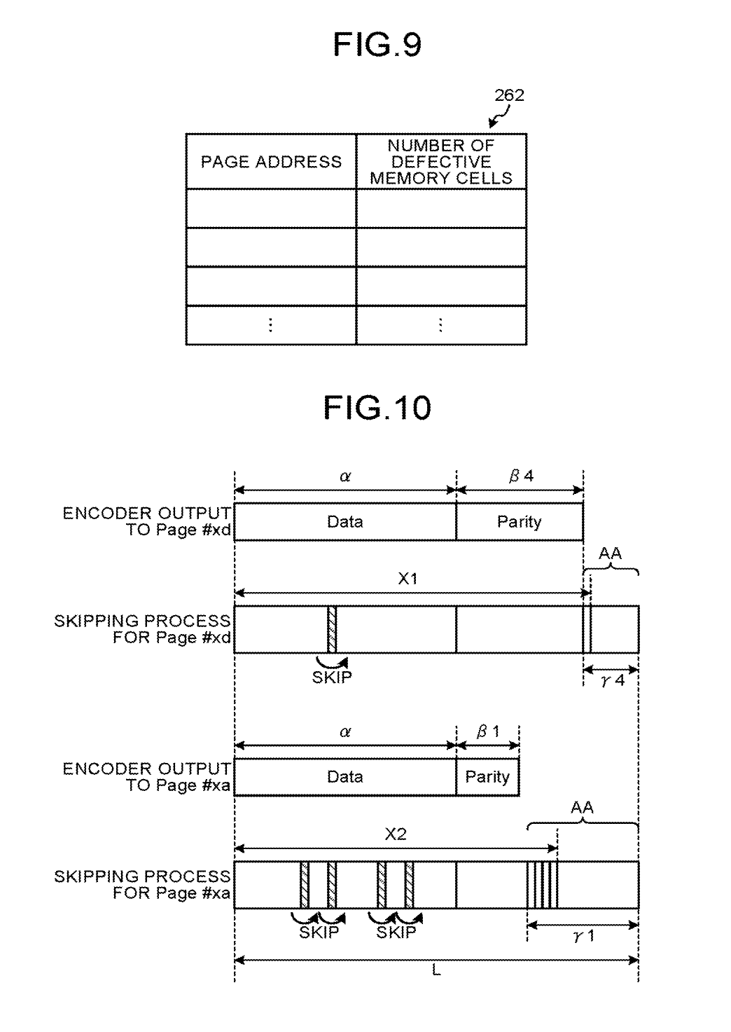

In this way, in this embodiment, the length of the parity inside a redundant data frame is different according to the number of defective memory cells inside the page (memory cell group). For this reason, the encoder 241 generates parity of a length that is different according to the number of defective memory cells inside the page. In addition, the decoder 242 executes a decoding process by using parity having a length that is different according to the number of defective memory cells inside the page. For this reason, in the defective memory cell information storing unit 261, in addition to the locational information of a defective memory cell, as illustrated in FIG. 9, defective cell number information 262 representing the number of defective memory cells in units of pages is included. The encoder 241 determines one of the first to fourth frame types to which a coding target page corresponds based on the page address of the coding target page and the defective cell number information 262 and executes a coding process based on a result of the determination. Similarly, the decoder 242 executes a decoding process based on the result of the determination.

Next, the defective cell avoiding process executed by the storage location control unit 26 will be described. FIG. 10 illustrates an example in which a skipping process is executed as the defective cell avoiding process. FIG. 10 is a diagram that illustrates an encoder output to page #xd illustrated in FIG. 8, a skipping process for page #xd, an encoder output to page #xa illustrated in FIG. 8, and a skipping process for page #xa. At a first stage of FIG. 10, a codeword output from the encoder 241 at the time of writing data into page #xd is illustrated. This codeword includes data having a length of α and parity having a length of β4 that are included in the fourth frame structure. In other words, at the first stage of FIG. 10, a codeword to be output to a page belonging to the group in which the number of defective memory cells is the smallest is illustrated.

At a second stage of FIG. 10, a redundant data frame having the fourth frame structure that is output from the storage location control unit 26 at the time of writing data into page #xd is illustrated. In FIG. 10, a hatched portion illustrates a portion corresponding to a defective memory cell. In other words, the hatched portion represents a portion at which the storage destination is a defective memory cell in a case where a redundant data frame is stored. Page #xd belongs to the group in which the number of defective memory cells is the smallest, and, at the second stage of FIG. 10, a case is illustrated in which one defective memory cell occurs. As illustrated at the second stage of FIG. 10, by skipping the defective memory cell, the storage location of the end of the codeword is shifted to the right side on the sheet by a length corresponding to the defective memory cell. For this reason, the head to the end of the codeword corresponds to X1 bits (X1 memory cells). In a case where the skipping process illustrated in FIG. 10 is executed, the storage location control unit 26 sequentially outputs input codewords to the memory I/F 22. At this time, the storage location control unit 26 outputs, as data stored at a bit location at which the writing destination corresponds to a defective memory cell in the codeword, an arbitrary value (for example, “1”) instead of the data stored at the bit location in the codeword based on the defective memory cell information and then outputs the data stored at the bit location of the codeword after the output of the arbitrary value. In other words, the storage location control unit 26 outputs data acquired by inserting an arbitrary value at a bit location at which the writing destination corresponds to a defective memory cell into the codeword output from the encoder 241 illustrated at the first stage of FIG. 10. In other words, before the data of a bit location at which the writing destination corresponds to a defective memory cell, an arbitrary value having the same length as the data is inserted. Thereafter, the storage location control unit 26 outputs an arbitrary value (for example, “1”) until a bit length from the head of the data frame becomes L (=α+β4+γ4) bits. In this way, the data output from the storage location control unit 26 is the defect avoidance data of the storage location control unit 26 described above. In this embodiment, such a process is executed for each of the redundant data frames D1 and D2 illustrated in FIG. 8.

At a third stage of FIG. 10, a codeword output from the encoder 241 at the time of writing data into page #xa is illustrated. This codeword includes data having a length of α and parity having a length of β1 that are included in the first frame structure. In other words, at the third stage of FIG. 10, a codeword to be output to a page belonging to the group in which the number of defective memory cells is the largest is illustrated.

At a fourth stage of FIG. 10, a redundant data frame having the first frame structure that is output from the storage location control unit 26 at the time of writing data into page #xa is illustrated. Page #xa belongs to the group in which the number of defective memory cells is the largest, and, at the fourth stage of FIG. 10, a case is illustrated in which four defective memory cells occur. As illustrated at the fourth stage of FIG. 10, by skipping the four defective memory cells, the storage location of the end of the codeword is shifted to the right side on the sheet by a length corresponding to the number (four) of the defective memory cells. For this reason, the head to the end of the codeword corresponds to X2 bits (X2 memory cells). In a case where the skipping process is executed, the storage location control unit 26, as described above, before the data of a bit location at which the writing destination corresponds to a defective memory cell, inserts an arbitrary value having the same length as the data. Thereafter, the storage location control unit 26 outputs an arbitrary value (for example, “1”) until a bit length from the head of the data frame is L (=α+β1+γ1) bits. In this embodiment, such a process is executed for each of the redundant data frames A1 and A2 illustrated in FIG. 8.

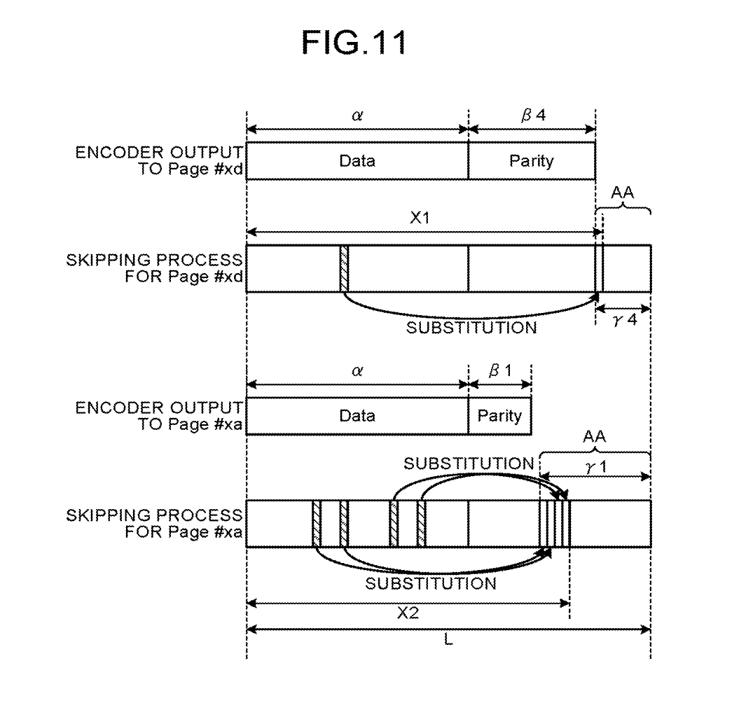

FIG. 11 illustrates an example in which a substitution process is executed as the defective cell avoiding process. FIG. 11 is a diagram that illustrates an encoder output to page #xd illustrated in FIG. 8, a substitution process for page #xd, an encoder output to page #xa illustrated in FIG. 8, and a substitution process for page #xa. At a first stage of FIG. 11, similar to the first stage of the example illustrated in FIG. 10, a codeword to be output to a page belonging to the group in which the number of defective memory cells is the smallest is illustrated.

At a second stage of FIG. 11, a redundant data frame having the fourth frame structure that is output from the storage location control unit 26 at the time of writing data into page #xd is illustrated. In FIG. 11, a hatched portion illustrates a defective memory cell. At the second stage of FIG. 11, a case is illustrated in which one defective memory cell occurs. In this case, since the fourth frame structure is used, at the time of executing the substitution process, in each of the redundant data frames D1 and D2 illustrated in FIG. 8, first (α+β4) bits are defined as a normal writing area, and γ4 bits of the end (tail) are defined as an alternative area AA for the substitution process. In other words, as illustrated at the second stage of FIG. 11, in a case where a defective memory cell is present, data is written into the alternative area AA having the length of γ4 bits instead of writing the data into the defective memory cell. In a case where the substitution process illustrated in FIG. 11 is executed, the storage location control unit 26 sequentially outputs input codewords to the memory I/F 22. At this time, the storage location control unit 26 outputs, as data stored at a bit location at which the writing destination corresponds to a defective memory cell in the codeword, an arbitrary value (for example, “1”) instead of the data stored at the bit location (first bit location) in the codeword based on the defective memory cell information, outputs data stored at a next bit location (second bit location) of the first bit location of the codeword after the output of the arbitrary value, and, after outputting up to the end of the codeword, outputs the data stored at the first bit location of the codeword. Then, until the bit length from the head of the data frame becomes L (=α+β4+γ4) bits, the storage location control unit 26 outputs an arbitrary value (for example, “1”). In this embodiment, such a process is executed for each of the redundant data frames D1 and D2 illustrated in FIG. 8.

At a third stage of FIG. 11, a codeword output from the encoder 241 at the time of writing data into page #xa is illustrated. As this codeword, similar to the third stage of FIG. 10, a codeword to be output to a page belonging to a group in which the number of defective memory cells is the largest is illustrated. This codeword includes data having a length of α and parity having a length of β1.

At a fourth stage of FIG. 11, a data frame having the first frame structure that is output from the storage location control unit 26 at the time of writing data into page #xa is illustrated. At the fourth stage of FIG. 11, a case is illustrated in which four defective memory cells occur. As illustrated at the fourth stage of FIG. 11, the storage location control unit 26 writes data corresponding to four pieces into the alternative area AA having a length of γ1 bits instead of writing the data into the four defective memory cells. In addition, in a case where the substitution process is executed, the storage location control unit 26 outputs, as data stored at a bit location at which the writing destination corresponds to a defective memory cell in the codeword, an arbitrary value (for example, “1”) instead of the data stored at the bit location (first bit location) in the codeword based on the defective memory cell information, outputs data stored at a next bit location (second bit location) of the first bit location of the codeword after the output of the arbitrary value, and, after outputting up to the end of the codeword, outputs the data stored at the first bit location of the codeword. Then, such a process is repeatedly executed in correspondence with a bit location corresponding to each defective memory cell. Then, until the bit length from the head of the data frame becomes L (=α+β1+γ1) bits, the storage location control unit 26 outputs an arbitrary value (for example, “1”). In this embodiment, such a process is executed for each of the redundant data frames D1 and D2 illustrated in FIG. 8.

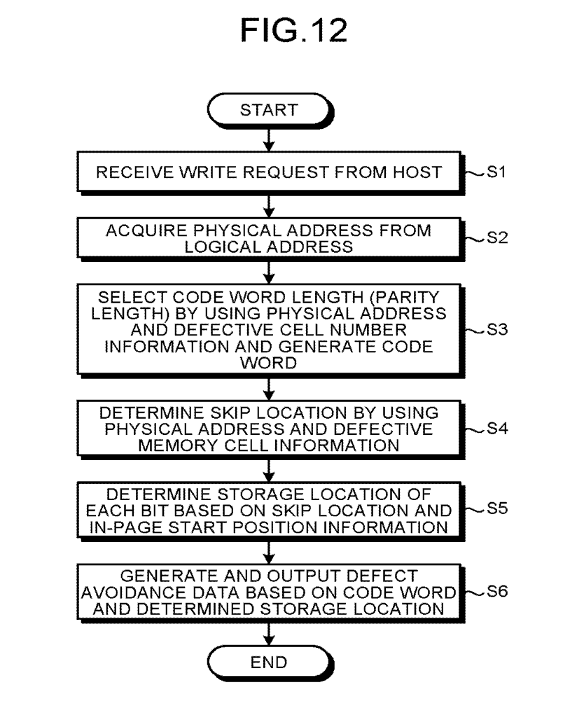

FIG. 12 is a flowchart that illustrates an example of a writing processing sequence according to this embodiment. As illustrated in FIG. 12, the control unit 23 receives a write request from the host 4 (Step S1) and acquires a physical address from a logical address of user data requested to be written (Step S2). Next, the encoder 241 selects a redundant data frame from the first to fourth frame types described above by using the physical address and the defective cell number information 262 illustrated in FIG. 9. In other words, since the data length α is the same a between the first to fourth frame types, the encoder 241 selects a length (codeword length) of the parity from lengths β1 to β4 by using the physical address and the defective cell number information 262 (Step S3). Then, the encoder 241 generates a codeword such that the parity has the selected length. The generated codeword is input to the storage location control unit 26.

The storage location control unit 26 selects a redundant data frame from the first to fourth frame types described above by using the physical address and the defective cell number information 262. In addition, the storage location control unit 26 determines a skipping location (skip position) by using the physical address and the defective memory cell information (Step S4). Then, the storage location control unit 26 determines a storage location of a codeword based on the skipping location and in-page head location information (Step S5). In other words, for example, the storage location illustrated at the second stage or the fourth stage of FIG. 10 is determined. Here, the in-page head location information is information that represents the location (column address) of the head of each redundant data frame illustrated in FIG. 8. The storage location control unit 26 executes the skipping process described above based on the codeword output from the encoder 241 and the storage location of each bit determined in Step S5, generates the selected redundant frame by adding an arbitrary value (for example, “1”) until the bit length becomes L bits, and outputs the generated redundant frame (Step S6). The process described above is executed in units of pages.

In FIG. 12, while an example in which the skipping process is executed is illustrated, in a case where the substitution process is executed, in Step S4 illustrated in FIG. 12, the storage location control unit 26 determines an alternative location by using the physical address and the defective memory cell information. More specifically, a bit location corresponding to a defective memory cell is acquired as the first bit location, and a destination location (second location) at which a bit value to be written into the first bit location is written is determined from the alternative area AA. The storage location control unit 26 stores the correspondence between the first bit location and the second bit location.

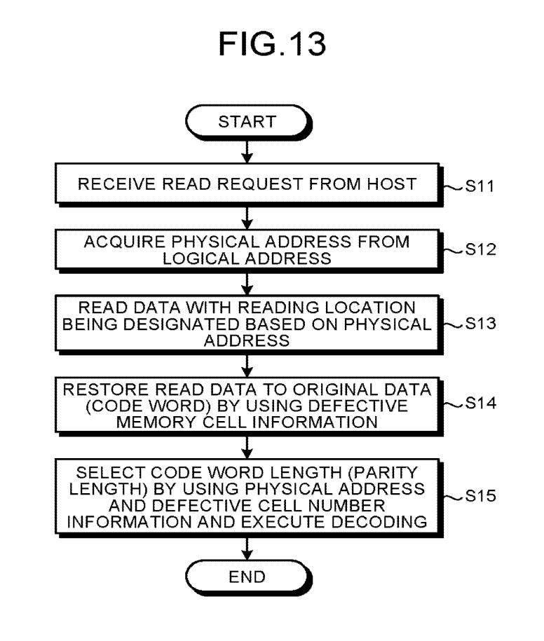

FIG. 13 is a flowchart that illustrates an example of a reading processing sequence according to this embodiment. The process illustrated in FIG. 13 is executed for each redundant data frame. As illustrated in FIG. 13, the control unit 23 receives a read request from the host 4 (Step S1) and acquires a physical address from a logical address of user data requested to be read (Step S12). Next, the control unit 23 instructs the memory I/F 22 to read data with a location of reading (physical address) being designated (Step S13). The memory I/F 22 reads data from the semiconductor memory unit 3 based on the instruction from the control unit 23.

Next, the storage location control unit 26 restores data corresponding to a codeword to be output to the decoder 242 from the redundant data frame read from the semiconductor memory unit 3 (Step S14). More specifically, the storage location control unit 26 selects a redundant data frame to which the read data belongs from the first to fourth frame types described above by using the physical address of the read data and the defective cell number information 262. The storage location control unit 26 acquires a data length of the arbitrary value added to the rear end portion of the alternative area AA and a bit location skipped as a defective memory cell in the read data by using the selected frame type and the defective memory cell information and removes the added data and data of the skipped bit location, in other words, the bit into which the arbitrary value has been inserted at the time of writing the data from the read redundant data frame.

In addition, in a case where not the skipping process but the substitution process is executed at the time of writing data, the storage location control unit 26 acquires the data length of the arbitrary value added to the rear end portion of the alternative area AA by using the selected frame type and the defective memory cell information. The storage location control unit 26 removes the added data from the read redundant data frame based on the acquisition. In addition, the storage location control unit 26 substitutes, in other words, overwrites the data stored at the first bit location with the data stored at the second bit location based on the stored correspondence between the first bit location and the second bit location. The storage location control unit 26 inputs data corresponding to the restored codeword to the decoder 242.

The decoder 242 selects a redundant data frame to which the input codeword belongs from the first to fourth frame types described above and acquires the length (codeword length) of the parity by using the physical address of the read data and the defective cell number information 262. The decoder 242 decodes data input from the storage location control unit 26 based on the acquired length of the parity and executes an error correction in a case where an error is present (Step 15).

In this way, in the embodiment, the length of the parity and the length of the alternative area AA inside the redundant data frame are changed in accordance with the number of defective memory cells. In other words, in a case where the number of defective memory cells is large, the length of the parity is shortened, and the length of the alternative area AA is lengthened. On the other hand, in a case where the number of defective memory cells is small, the length of the parity is lengthened, and the length of the alternative area AA is shortened. For this reason, in this embodiment, the reliability can be improved also for a memory chip having many defective memory cells.

The data may be read not in units of codewords (units of redundant frames) but in units of pages. In addition, while the redundant frame configuration has been described to be changed in units of pages, the redundant frame configuration may be changed in units of codewords.

In addition, the redundant frame structure may be changed after the use of the memory system 1 progresses. For example, when the use of the memory system 1 progresses, the number of defective memory cells increases, and the performance of the memory system 1 is degraded. In such a situation, there are cases where a process is executed in which the size of the divided data inside a page described above is decreased to be less than the size at the time of shipment. By executing this process, the error correction capability can be improved without increasing the circuit scale that is necessary for coding and decoding. Accordingly, when such a process is executed, the redundant frame structure may be changed.

In this embodiment, while a case in which the codeword is a systematic code configured by data and parity has been described, the codeword generated by the encoder 241 may be a codeword that is not separated into data and parity.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a nonvolatile memory; and
a controller configured to:
manage information including defective memory cell information of the nonvolatile memory,
when a write request including first data is received, select one frame type from among a plurality of frame types including first and second frame types based on the information and generate a codeword including the first data and in correspondence with the selected frame type, the first frame type including a first codeword and a first alternative area, the first codeword including data having a first length and redundant data having a second length, the first alternative area having a third length, the second frame type including a second codeword and a second alternative area, the second codeword including data having the first length and redundant data having a fourth length, the second alternative area having a fifth length, the second length being longer than the fourth length, the third length being shorter than the fifth length, the plurality of frame types having a same sixth length,
in a case where selecting the first frame type, generate a frame corresponding to the first frame type having the sixth length based on the information and the first codeword and write the generated frame corresponding to the first frame type into the nonvolatile memory, and
in a case where selecting the second frame type, generate a frame corresponding to the second frame type having the sixth length based on the information and the second codeword and write the generated frame corresponding to the second frame type into the nonvolatile memory.

2. The memory system according to claim 1,
wherein the defective memory cell information includes the number of defective memory cells per first area inside the nonvolatile memory, and
wherein the controller is configured to
in a case where the number of defective memory cells of the first area including a second area in which the first codeword is written is less than a threshold, select the first frame type, and
in a case where the number of the defective memory cells of the first area including the second area is more than the threshold, select the second frame type.

3. The memory system according to claim 2,
wherein the defective memory cell information includes locational information of a defective memory cell, and
wherein the controller generates the frame corresponding to the first frame type and the frame corresponding to the second frame type based on the locational information of the defective memory cell.

4. The memory system according to claim 1, wherein, when a read request for the first data is received, the controller is configured to
read the frame from the nonvolatile memory,
determine a frame type to which the first data belongs based on the information,
in a case where the frame type to which the first data belongs is determined to be the first frame type, restore the first codeword from the read frame and restore the first data from the restored first codeword, and
in a case where the frame type to which the first data belongs is determined to be the second frame type, restore the second codeword from the read frame and restore the first data from the restored second codeword.

5. The memory system according to claim 4, wherein,
in a case where selecting the first frame type, and in a case where the defective memory cell is present in memory cells for writing the first codeword, the controller generates a frame corresponding to the first frame type by inserting third data before second data, a memory cell for storing the second data being the defective memory cell, the third data having a same size as the second data,
in a case where selecting the second frame type, and in a case where the defective memory cell is present in memory cells for writing the second codeword, the controller generates a frame corresponding to the second frame type by inserting fifth data before fourth data, a memory cell for storing the fourth data being the defective memory cell, the fifth data having a same size as the fourth data.

6. The memory system according to claim 5, wherein,
in a case where selecting the first frame type, the controller adds arbitrary sixth data after the first codeword in which the third data is inserted to generate a frame corresponding to the first frame type having the sixth length, and
in a case where selecting the second frame type, the controller adds arbitrary seventh data after the second codeword in which the fifth data is inserted to generate a frame corresponding to the second frame type having the sixth length.

7. The memory system according to claim 6, wherein,
in a case where the frame type to which the first data belongs is determined to be the first frame type, the controller removes the third data and the sixth data from the read frame to restore the first codeword, and
in a case where the frame type to which the first data belongs is determined to be the second frame type, the controller removes the fifth data and the seventh data from the read frame to restore the second codeword.

8. The memory system according to claim 4, wherein,
in a case where selecting the first frame type, and in a case where the defective memory cell is present in memory cells for writing the first codeword, the controller generates a frame corresponding to the first frame type by overwriting eighth data with arbitrary ninth data and inserting tenth data after the first codeword, a memory cell for storing the eighth data being the defective memory cell, the tenth data being the eighth data before the overwriting,
in a case where selecting the second frame type, and in a case where the defective memory cell is present in memory cells for writing the second codeword, the controller generates a frame corresponding to the second frame type by overwriting eleventh data with arbitrary twelfth data and inserting thirteenth data after the second codeword, a memory cell for storing the eleventh data being the defective memory cell, the thirteenth data being the eleventh data before the overwriting.

9. The memory system according to claim 8, wherein,
in a case where selecting the first frame type, the controller adds arbitrary fourteenth data after the first codeword in which the tenth data is inserted to generate a frame corresponding to the first frame type having the sixth length, and
in a case where selecting the second frame type, the controller adds arbitrary fifteenth data after the first codeword in which the thirteenth data is inserted to generate a frame corresponding to the second frame type having the sixth length.

10. The memory system according to claim 9, wherein,
in a case where the frame type to which the first data belongs is determined to be the first frame type, the controller restores the first codeword by removing the fourteenth data from the read frame and overwriting sixteenth data with the tenth data, a memory cell stored the sixteenth data being the defective memory cell, and
in a case where the frame type to which the first data belongs is determined to be the second frame type, the controller restores the second codeword by removing the fifteenth data from the read frame and overwriting seventeenth data with the thirteenth data, a memory cell stored the seventeenth data being the defective memory cell.

11. A method of controlling nonvolatile memory, the method comprising:
managing information including defective memory cell information of the nonvolatile memory,
when a write request including first data is received, selecting one frame type from among a plurality of frame types including first and second frame types based on the information and generating a codeword including the first data and in correspondence with the selected frame type, the first frame type including a first codeword and a first alternative area, the first codeword including data having a first length and redundant data having a second length, the first alternative area having a third length, the second frame type including a second codeword and a second alternative area, the second codeword including data having the first length and redundant data having a fourth length, the second alternative area having a fifth length, the second length being longer than the fourth length, the third length being shorter than the fifth length, the plurality of frame types having a same sixth length,
in a case where selecting the first frame type, generating a frame corresponding to the first frame type having the sixth length based on the information and the first codeword and writing the generated frame corresponding to the first frame type into the nonvolatile memory, and
in a case where selecting the second frame type, generating a frame corresponding to the second frame type having the sixth length based on the information and the second codeword and writing the generated frame corresponding to the second frame type into the nonvolatile memory.

12. The method according to claim 11,
wherein the defective memory cell information includes the number of defective memory cells per first area inside the nonvolatile memory, the method further comprising:
in a case where the number of defective memory cells of the first area including a second area in which the first codeword is written is less than a threshold, selecting the first frame type, and
in a case where the number of the defective memory cells of the first area including the second area is more than the threshold, selecting the second frame type.

13. The method according to claim 12,
wherein the defective memory cell information includes locational information of a defective memory cell, and
wherein the frame corresponding to the first frame type and the frame corresponding to the second frame type are generated based on the locational information of the defective memory cell.

14. The method according to claim 11, further comprising:
when a read request for the first data is received,
reading the frame from the nonvolatile memory;
determining a frame type to which the first data belongs based on the information;
in a case where the frame type to which the first data belongs is determined to be the first frame type, restoring the first codeword from the read frame and restoring the first data from the restored first codeword; and
in a case where the frame type to which the first data belongs is determined to be the second frame type, restoring the second codeword from the read frame and restoring the first data from the restored second codeword.

15. The method according to claim 14, further comprising:
in a case where selecting the first frame type, and in a case where the defective memory cell is present in memory cells for writing the first codeword, generating a frame corresponding to the first frame type by inserting third data before second data, a memory cell for storing the second data being the defective memory cell, the third data having a same size as the second data,
in a case where selecting the second frame type, and in a case where the defective memory cell is present in memory cells for writing the second codeword, generating a frame corresponding to the second frame type by inserting fifth data before fourth data, a memory cell for storing the fourth data being the defective memory cell, the fifth data having a same size as the fourth data.

16. The method according to claim 15, further comprising:
in a case where selecting the first frame type, adding arbitrary sixth data after the first codeword in which the third data is inserted to generate a frame corresponding to the first frame type having the sixth length, and
in a case where selecting the second frame type, adding arbitrary seventh data after the second codeword in which the fifth data is inserted to generate a frame corresponding to the second frame type having the sixth length.

17. The method according to claim 16, further comprising:
in a case where the frame type to which the first data belongs is determined to be the first frame type, removing the third data and the sixth data from the read frame to restore the first codeword, and
in a case where the frame type to which the first data belongs is determined to be the second frame type, removing the fifth data and the seventh data from the read frame to restore the second codeword.

18. The method according to claim 14, further comprising:
in a case where selecting the first frame type, and in a case where the defective memory cell is present in memory cells for writing the first codeword, generating a frame corresponding to the first frame type by overwriting eighth data with arbitrary ninth data and inserting tenth data after the first codeword, a memory cell for storing the eighth data being the defective memory cell, the tenth data being the eighth data before the overwriting,
in a case where selecting the second frame type, and in a case where the defective memory cell is present in memory cells for writing the second codeword, generating a frame corresponding to the second frame type by overwriting eleventh data with arbitrary twelfth data and inserting thirteenth data after the second codeword, a memory cell for storing the eleventh data being the defective memory cell, the thirteenth data being the eleventh data before the overwriting.

19. The method according to claim 18, further comprising:
in a case where selecting the first frame type, adding arbitrary fourteenth data after the first codeword in which the tenth data is inserted to generate a frame corresponding to the first frame type having the sixth length, and
in a case where selecting the second frame type, adding arbitrary fifteenth data after the first codeword in which the thirteenth data is inserted to generate a frame corresponding to the second frame type having the sixth length.

20. The method according to claim 19, further comprising:
in a case where the frame type to which the first data belongs is determined to be the first frame type, restoring the first codeword by removing the fourteenth data from the read frame and overwriting sixteenth data with the tenth data, a memory cell stored the sixteenth data being the defective memory cell, and
in a case where the frame type to which the first data belongs is determined to be the second frame type, restoring the second codeword by removing the fifteenth data from the read frame and overwriting seventeenth data with the thirteenth data, a memory cell stored the seventeenth data being the defective memory cell.
